(19) United States
(12) Patent Application Publication
(10) Pub. No.: US 2001/0054755 A1
(43) Pub. Date: Dec. 27, 2001

(54) Integrated package and RFID antenna

(76) Inventor: Richard Kirkham, Loveland, OH (US)

Correspondence Address: GIBBONS, DEL DEO, DOLAN, GRIFFINGER & VECCHIONE, 1 RIVERFRONT PLAZA, NEWARK, NJ, 07102-5497, US

(21) Appl. No.: 09/835,095

(22) Filed: Apr. 13, 2001

Related U.S. Application Data
(60) Provisional application No. 60/196,996, filed on Apr. 13, 2000.
(60) Provisional application No. 60/196,948, filed on Apr. 13, 2000.

(51) Int. Cl. H01L 23/02

(52) U.S. Cl. 257/678

(57) ABSTRACT

The present invention is an RFID tag system for a package comprising an RFID tag having an antenna. The RFID tag is coupled to the package. An RFID antenna, is capacitively coupled to a conductive package or content material wherein said conductive package or content material forms a part of an RF antenna design.

### CROSS-REFERENCES TO RELATED APPLICATIONS

This application claims the benefit of U.S. Provisional Application Ser. Nos. 60/196,996 and 60/196,948 filed on Apr. 13, 2000 which are hereby incorporated by reference.

### FIELD OF THE INVENTION

This invention relates to the field of packaging, and more particularly to a package interfacing to a computer system.

### BACKGROUND OF THE INVENTION

The ability of an RFID (Radio Frequency Identification) tag to be interrogated is directly related to the range of its antenna. While interrogator antennas are configured in a variety of designs, RFID tag antennas generally are limited by the configuration of the RFID tag. Conventional RFID tag designs utilize an integrated approach in which the various RFID tag components are incorporated in a single, self-contained unit. The advantages of such systems allow a retailer to purchase RFID tag devices as a store security feature in which the RFID tags may be added to high-end items and other merchandise susceptible to theft. In such an approach, an RFID tag is affixed to clothing or packages such as electronic equipment and music CDs. Typically, RFID tags affixed to packaging require a flat planar surface for attachment. While fit for their intended purpose on many large high-end items and packaging having flat planar surfaces, such self-contained RFID tags are difficult to affix to some high-end packaging such as cylindrical lipstick containers. The cylindrical shape can make the attachment of an RFID tag to a lipstick container difficult. Moreover, the lipstick container usually is designed with certain aesthetic features to attract the consumer. These features may be lost or obscured when the retailer affixes an RFID tag. Finally, when affixed, the position of the RFID tag or deformation of the RFID tag on the product may significantly reduce the range of the antenna. Thus, a need exists for a way to improve the performance of RFID tags on a variety of packages, while maintaining a low cost to manufacture and a design that is complementary to the product design.

### SUMMARY OF THE INVENTION

The present invention relates to an RFID tag and package system that is based upon the realization that product packaging itself can provide features and advantages to RFID tag designs that have been ignored. The system of the present invention takes advantage of this realization and takes into consideration the RF properties of the package and package contents. The RFID tag antenna is designed integrally with the packaging materials and with a consideration of the package contents. The result is that the packaging materials and configuration that could detract from the performance of a self contained RFID are used to enhance the performance of the RFID tag antenna.

### BRIEF DESCRIPTION OF THE DRAWINGS

A more complete understanding of the present invention may be obtained from consideration of the following description in conjunction with the drawing in which:

FIG. 1 is a functional overview of a radio frequency identification system;

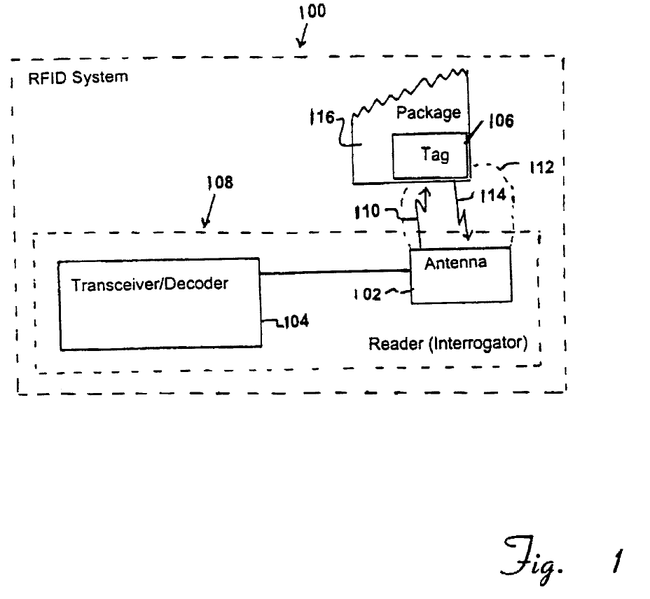

FIG. 2 is a detail of an RFID;

FIG. 3 is a detail of an RFID utilizing a capacitively coupled antenna;

FIGS. 4A-D is a diagram of a plurality of package container shapes; and

FIG. 5 is a detail of an RFID utilizing a capacitive coupling to an antenna formed at least in part by the package itself.

### DETAILED DESCRIPTION

Although the present invention is particularly well suited for active RFID tags formed integrally with packages, and shall be so described, the present invention is equally well suited for use in other applications of RFID tags including, but not limited to, passive RFID tags.

Radio Frequency Identification (RFID) system 100 essentially comprises three components: a reader antenna or coil 102; a transceiver (with decoder) 104; and a transponder (commonly called an RF tag) 106 programmed with unique information (data).

The antenna 102 emits radio signals to activate the tag 106 and to read and write data to the tag 106. Reader antennas come in a variety of shapes and sizes. For example, they can be built into a doorway to receive tag data from persons or things passing through the door. The electromagnetic field produced by an antenna 102 can be constantly present when multiple tags 106 are expected to be presented continually. If constant interrogation is not required, a sensor device can activate the field.

Often the antenna 102 is configured with the transceiver/decoder 104 to become a reader (interrogator) 108, which can be configured either as a handheld or a fixed-mount device. The reader 108 emits radio waves 110 at ranges of anywhere from one inch to 100 feet or more, depending upon reader power output and the radio frequency employed. When an RFID tag 106 passes through an electromagnetic zone 112, tag 106 detect a reader activation signal and responds by emitting radio waves 114. The reader 108 decodes the data encoded in the tag's integrated circuit and the data is passed to a host computer for processing.

RFID tags 102 come in a wide variety of shapes and sizes. RFID tags 102 may be categorized as either active or passive. Active RFID tags 102 are powered by an internal battery and are typically read/write, i.e., tag data can be rewritten and/or modified. An active tag's memory size varies according to application requirements; some systems operate with up to 1 MB of memory. In a typical read/write RFID system 100, a tag 106 can provide a set of instructions, and the tag 106 can receive information (encoded data). This encoded data then becomes part of the history of the tagged product 116. The battery-supplied power of an active tag generally gives it a greater read range. Trade offs are greater size, greater cost, and a limited operational life.

Passive RFID tags 106 operate without a separate external power source and obtain operating power generated from the reader 104. Passive tags 106 are consequently much lighter than active tags, less expensive, and offer a virtually unlimited operational lifetime. The trade off is that passive tags 106 have shorter read ranges than active tags and require a higher-powered reader.

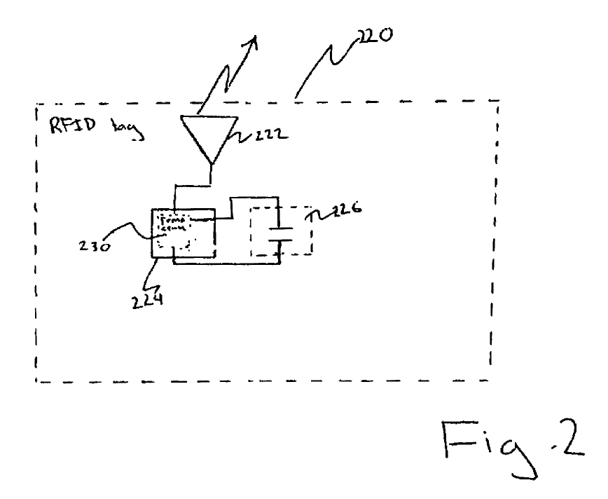

Referring to FIG. 2 a detailed functional overview of an RFID tag 220 is shown. RFID tag 220 comprises of an antenna 222, a transponder 224 and an energy storage device 226. The RFID tag 220, in response to being interrogated, transmits a radio frequency response. The present invention takes advantage of a design wherein portions of the RFID tag 220, such as the antenna 222 and the energy storage device 226 are printed on or otherwise formed integrally with a package or label. The transponder 224 can be an application specific integrated circuit (ASIC) or other suitable technology that is known to those skilled in the art. In response to a predetermined form or query or code the transponder 224 activates a transceiver 230.

Read-only tags are typically passive and are programmed with a unique set of data (usually 32 to 128 bits) that cannot be modified. Read-only tags most often operate as a key or index into a database containing modifiable product-specific information.

Frequency ranges also distinguish RFID systems. Low-frequency (30 kHz to 500 kHz) systems have short reading ranges and lower system costs. They are most commonly used in security access, asset tracking, and animal identification applications. High-frequency (850 MHz to 950 MHz and 2.4 GHz to 2.5 GHz) systems, offer long read ranges (greater than 90 feet) and high reading speeds.

The significant advantage of RFID systems is the non-contact, non-line-of-sight nature of the technology. Tags can be read through a variety of substances such as snow, fog, ice, paint, crusted grime, and other visually and environmentally challenging conditions, where barcodes or other optically read technologies would be at a disadvantage. RFID tags can also be read in challenging circumstances at significant speed, in most cases responding in less than 100 milliseconds.

The range that can be achieved in an RFID system is determined in part by the power available at the reader/interrogator to communicate with the tag(s); power available within the tag to respond; and environmental conditions and structures, the former being more significant at higher frequencies including signal to noise ratio.

Although the level of available power is a significant determinant of range, the manner and efficiency in which that power is deployed also influences the range. The field or wave delivered from an antenna extends into the space surrounding it and its strength diminishes with respect to distance. The antenna design will determine the shape of the field or propagation wave delivered, so that range will also be influenced by the angle subtended between the tag and antenna.

In space free of any obstructions or absorption mechanisms the strength of the field declines in inverse proportion to the square of the distance. For a wave propagating through a region in which reflections can arise from the ground and from obstacles, the reduction in strength can vary quite considerably, in some cases as an inverse fourth power of the distance. Where different paths arise in this way, the phenomenon is known as “multi-path attenuation”. At higher frequencies absorption due to the presence of moisture can further influence range. It is therefore important in many applications to determine how the environment, internal or external, can influence the range of communication. Where a number of reflective metal ‘obstacles’ are encountered within the application, and can vary in number from time to time, it may also be necessary to establish the implications of such changes through an appropriate environmental evaluation.

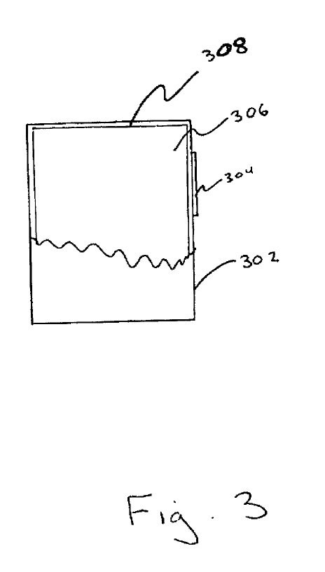

Referring to FIG. 3, a representative embodiment of an RFID utilizing a capacitively coupled antenna is shown. Antenna aperture size can be increased resulting in increased RFID range and reduction of dead zones typically caused by package and reader orientation. Typically, at some alignments of a package 302 (shown partially cut away) having an RFID antenna 304 with respect to reader/interrogator antenna (not shown), dead zones may exist where no detectable energy is received by the RFID antenna 304. Capacitive coupling of the RFID antenna 304 to package contents 306 can provide an enhanced package antenna 306, and the antenna aperture size is increased. Typically the package contents or packaging material have been considered to be a barrier for the radiation from RFID antenna 304. By proper design and selection of the RFID antenna 304 and the material and/or contents of package 306, what was a barrier becomes a device for increasing antenna aperture. The RFID antenna 304 in one embodiment can be a conductive label, which contains a printed antenna. The label antenna is designed to excite a predetermined electromagnetic mode onto the surface of the package. At frequencies where the circumference of a conductive medium within a cylindrical package is on the order of one half the wavelength of the frequency of operation of the RFID, capacitive coupling induces currents and excites the package contents 306. Where the package 302 is made of a conductive material, the package itself will be excited with a corresponding surface current.

By adjusting the separation of the capacitive coupler and the package, such as by adjusting the shape of the capacitive coupler (RFID antenna 304), maximum power transfer can be approached between the enhanced package antenna 306 and the RFID antenna 304.

By increasing the antenna aperture, increased range for the RFID system is accomplished without requiring an increase in effective isotropic radiated power (EIRP) from the reader, thereby not exceeding FCC and European safety regulations for radiated power.

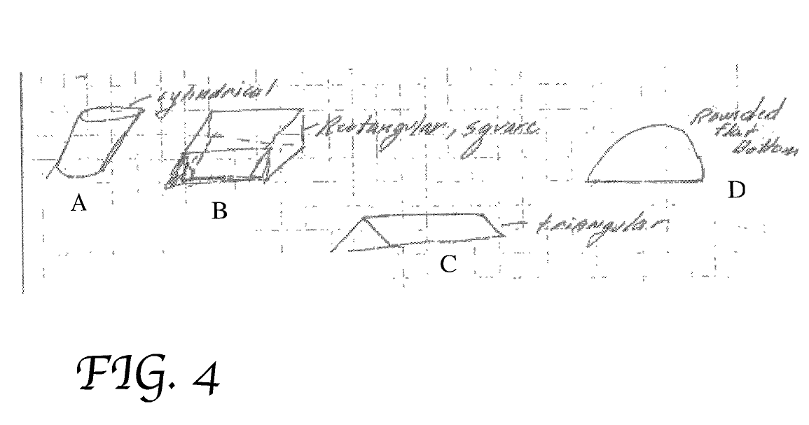

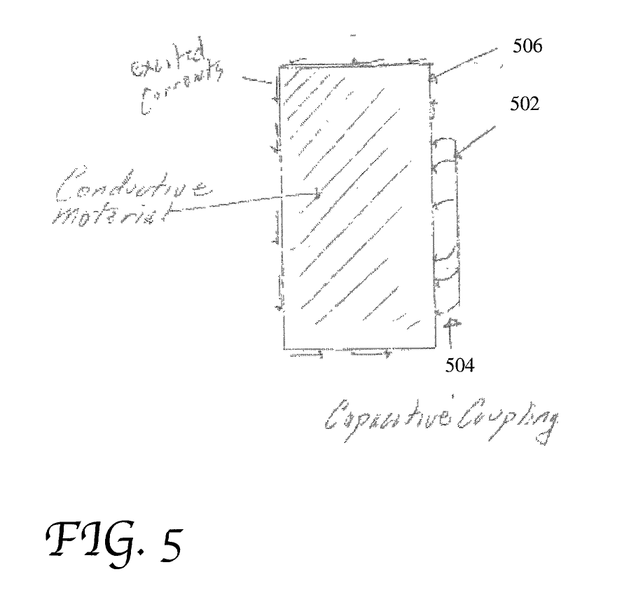

Antennas comprised of conductive resins, conductive inks, conductive polymers and metals vary in degree of conductivity. An RFID circuit (or radio frequency integrated circuit) and embedded antenna may be coupled to additional antenna elements within or near a package. The coupling can be inductive, capacitive or electromagnetic. Proximity of the additional antenna elements and the frequency of operation determine the type of coupling mechanism. When the package contains a conductive resin, resistive loading occurs and the entire package becomes an antenna structure. Where the contents of a package are electrically conductive, such as a water-based solution, the contents of the package can be excited to behave as an antenna. The size, shape and configuration of the additional antenna elements including the coupling mechanism can be varied depending on frequency, range, packaging material, packaging contents, and environmental influences, such as humidity, moisture content, temperature, handling and transportation. With reference to FIGS. 4A-D, a variety of illustrative packaging configurations are shown including cylindrical (FIG. 4A), rectangular or square (FIG. 4B), triangular or pyramidal (FIG. 4C), and spherical, concave or convex (FIG. 4D). It should be appreciated that each of these configurations, presents a different RF propagation feature resulting in different antenna designs. In one embodiment of the present invention, a three dimensional finite element design approach is used for antenna design,. Where a pre-designed RFID circuit is selected, a package corresponding to product need is selected, and additional antenna elements are printed and connected with the RFID circuit. The elements may be printed across the package to increase the size of the antenna. Where the package is metallic or the package contents such as water may be subject to RF excitation, the antenna elements may be printed on a label 502 (FIG. 5) containing the RFID circuit in which the label adhesive 504 provides a sufficient dielectric constant to capacitively couple the antenna elements to the metallic package or package contents 506 to increase the antenna size. It will further be appreciated the label may be designed to complement or enhance the aesthetics of the package.

In view of the foregoing description, numerous modifications and alternative embodiments of the invention will be apparent to those skilled in the art. Accordingly, this description is to be construed as illustrative only and is for the purpose of teaching those skilled in the art the best mode of carrying out the invention.

We claim:

1. An integrated antenna RFID tag comprising:
a package containing a product, at least one of said package and product having an RF conductive element;
an RFID tag having an antenna element, said RFID tag being coupled to the package; and,
means for coupling said antenna element to said RF conductive element;
wherein said RF conductive element and said antenna element are integrally combined to function as an RF antenna.

2. The tag of claim 1 wherein said package has said RF conductive element.

3. The tag of claim 2 wherein said RF conductive element is a metallic layer.

4. The tag of claim 2 wherein said RF conductive element is a metallic paint applied to said package.

5. The tag of claim 1 wherein said RF conductive element is selected from the group consisting of conductive resins, conductive inks, conductive polymers and metals.

6. The tag of claim 1 wherein said coupling means is inductive.

7. The tag of claim 1 wherein said coupling means is capacitive.

8. The tag of claim 1 wherein said coupling means is electromagnetic.

9. The tag of claim 1 wherein said coupling means is electrical.

10. The tag of claim 1 wherein said product has said RF conductive element.

11. The tag of claim 10 wherein said RF conductive element is a liquid.

12. The tag of claim 11 wherein said liquid is subjected to excitation.

13. The tag of claim 11 wherein said liquid includes water.

14. The tag of claim 1 wherein said package has a shape selected from the group consisting of cylindrical, rectangular, triangular, pyramidal and spherical.

15. The tag of claim 7 wherein said antenna element is a metallic label and said coupling means is an adhesive material adapted to adhere said label to said package.

16. A method for producing an integrated antenna RFID tag comprising the steps of:
providing a product;
determining RF conductive properties of said product;
selecting a package adapted to contain said product, wherein said selection includes determining RF conductive properties of said product in combination with said package;
providing an RFID circuit to be coupled to said package and product;
designing an antenna element to connect to said RFID circuit utilizing said RF conductive properties; and
establishing an RF circuit between said antenna element, said RFID circuit, said package and product.

17. The method of claim 16 wherein said selecting step includes selecting a package material from the group consisting of conductive resins, conductive inks, conductive polymers and metals of varying conductivity.

18. The method of claim 17 wherein said designing step includes forming a coupling between said antenna element and said package.

19. The method of claim 18 wherein said coupling is selected from the group consisting of inductive, capacitive and electromagnetic couplings.

20. The method of claim 16 wherein said selecting step includes selecting a package shaped from the group consisting of cylindrical, rectangular, triangular and spherical shapes.
